(19) United States
(12) Patent Application Publication
(10) Pub. No.: US 2012/0012963 A1
(43) Pub. Date: Jan. 19, 2012

(54) MICRO DEVICE PACKAGING

(76) Inventors: Zhuqing Zhang, Corvallis, OR (US); Steve P. Hanson, Albany, OR (US); Chien-Hua Chen, Corvallis, OR (US)

(21) Appl. No.: 13/145,493

(22) PCT Filed: Feb. 27, 2009
(86) PCT No.: PCT/US09/35542

§ 371 Date: Jul. 20, 2011

(51) Int. Cl. H01L 31/0216

(52) U.S. Cl. 257/434; 438/68; 257/E31.119

(57) ABSTRACT

In one embodiment, a method for making an optical micro device package includes: providing a substrate wafer having a plurality of solid state light sensors integrate therein; providing a transparent cover wafer coated with a material that alters the transparency characteristics of the cover wafer; forming a layer of light sensitive, photo definable adhesive material on the substrate wafer; selectively removing part of the layer of adhesive material in a pattern for a plurality of adhesive spacers between the substrate wafer and the cover wafer with each spacer surrounding a corresponding one of the light sensors; bonding the substrate wafer and the cover wafer together at the spacers to form a wafer assembly in which each spacer surrounds and seals a corresponding one of the light sensors within a cavity bounded by a spacer and the two wafers; and singulating individual device packages from the wafer assembly.

### BACKGROUND

Optical micro-electro-mechanical system (MEMS) devices are often integrated into a silicon substrate using semiconductor processing techniques and then sealed under a glass cover to protect the device from environmental damage while still allowing light to reach the device. A Fabry Perot filter light receptor spectrophotometer, for example, uses solid state light sensors and Fabry Perot filters integrated into a silicon substrate. Some of the components in such spectrophotometers are very delicate, making them particularly susceptible to damage from the higher temperatures and contaminants present in conventional MEMS sealing/packaging processes.

### DRAWINGS

FIG. 1 is a plan view illustrating an optical micro device package according to one embodiment of the disclosure.

FIG. 2 is a section view taken along the line 2-2 in FIG. 1.

FIG. 3 is a plan view illustrating a micro device wafer assembly according to one embodiment of the disclosure.

FIG. 4 is a detail view of a portion of the wafer assembly shown in FIG. 3.

FIGS. 5-10 are section views illustrating one embodiment of a sequence of steps for processing a wafer assembly to form individual micro device packages such as the one shown in FIGS. 1 and 2.

FIGS. 11-15 are section views illustrating another embodiment of a sequence of steps for processing a wafer assembly to form individual micro device packages such as the one shown in FIGS. 1 and 2.

### DESCRIPTION

Embodiments of the present invention were developed in an effort to improve MEMS packaging for Fabry Perot filter light receptor spectrophotometers. Embodiments of the invention, however, are not limited to Fabry Perot filter light receptor spectrophotometer MEMS packaging but may be used in for packaging spectrophotometers in general as well as other types of optical MEMS devices. Hence, the following description should not be construed to limit the scope of the invention, which is defined in the claims that follow the description.

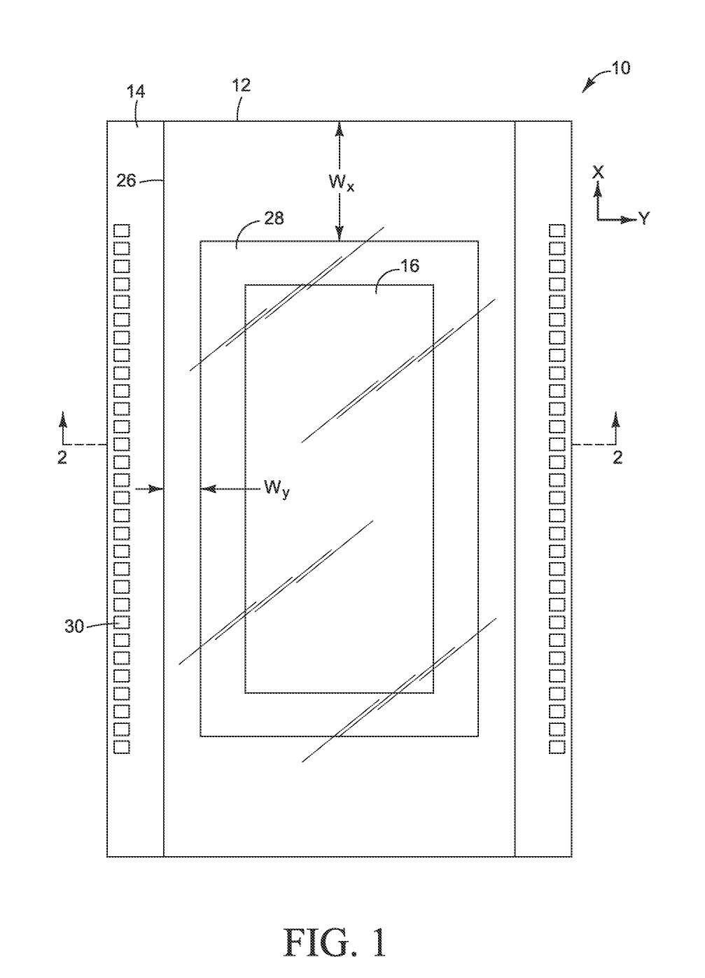

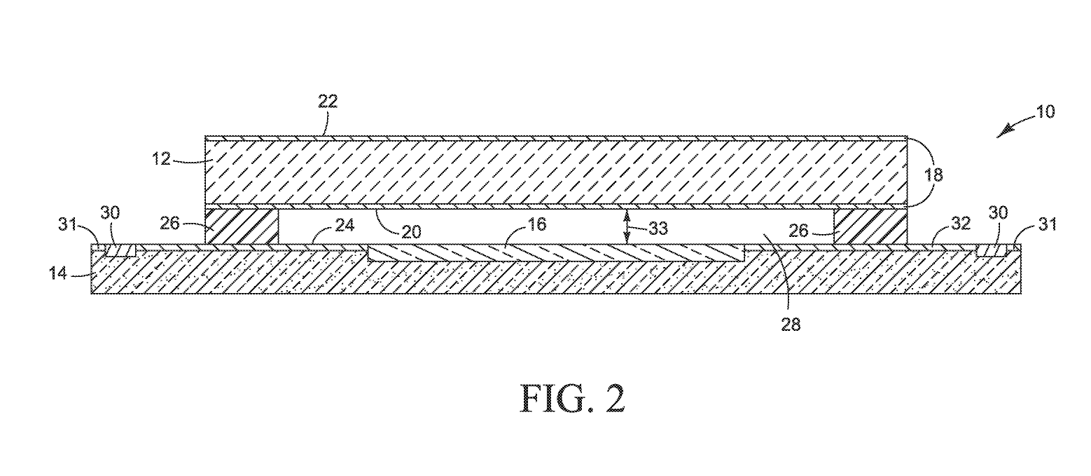

FIG. 1 is a plan view illustrating a micro device package 10 according to one embodiment of the disclosure. FIG. 2 is a section view taken along the line 2-2 in FIG. 1. Referring to FIGS. 1 and 2, device package 10 includes a glass or other suitable transparent cover 12, a substrate 14 and an optical micro device 16 integrated into substrate 14. Micro device 16 represents generally one or more optical devices that include a solid state light sensor, such as a Fabry Perot filter light receptor spectrophotometer for example. Cover 12 may also include a coating 18 on one or both surfaces 20, 22 to filter some wavelengths, to deter reflection (an “anti-reflection” coating), and/or to otherwise alter the characteristics of transparent cover 12. In a package 10 for Fabry Perot filter light receptor spectrophotometer device 16, for example, cover 12 typically will include anti-reflective coatings 18.

“Transparent” means the property of transmitting electromagnetic radiation along at least that part of the spectrum that includes wavelengths of infrared, visible and/or ultra-violet light. The nature or degree of transparency for cover 12 may vary according to the characteristics of optical device 16. For example, for an optical micro device 16 used to modulate color in a digital projector or to measure color in a Fabry Perot filter light receptor spectrophotometer, cover 12 will be transparent at least to visible light but need not be transparent to infrared and ultraviolet light. In another example, for an optical micro device 16 used to generate, modulate or detect light in the infrared range, cover 12 will be transparent at least to infrared light but need not be transparent to visible and ultraviolet light.

A primary surface 20 on cover 12 is affixed to a primary surface 24 on substrate 14 by a spacer 26 that surrounds micro device 16. Micro device 16 is enclosed within a cavity 28 defined by cover 12, substrate 14 and spacer 26. Electrical contact pads 30 are positioned along an exposed periphery 31 of substrate 14 for making electrical contact to micro device 16 through a circuit structure (not shown) integrated into substrate 14. In the embodiment shown, coating 18 forms cover primary surface 20 at spacer 26 and a layer 32 forms substrate primary surface 24 at spacer 26. Layer 32 represents generally, for example, a layer of silicon dioxide, silicon nitride, or silicon carbide, a polymeric passivation layer, or metal traces, or a combination of any such elements, that may be exposed along substrate surface 24.

As described in more detail below, spacer 26 is formed from an SU-8 photoresist (commercially available from Microchem Corp.) or another suitable light sensitive, photo definable adhesive material that is fully curable at lower temperatures. SU-8 photoresists are epoxy based negative resists fully curable at temperatures under 300° C. that will adhere to and seal a variety of materials commonly used in micro device fabrication and packaging. Although spacer 26 is shown bonding together surface coating 18 on cover 12 and a layer 32 on substrate 14, other configurations are possible. For example, an SU-8 or other suitable light sensitive adhesive material spacer 26 could be used to bond a glass or other transparent cover 12 directly to the surface of a silicon substrate 14.

With continued reference to FIGS. 1 and 2, in one example embodiment for a spectrophotometer MEMS device 16, a gap 33 of 20 μm-50 μm should be maintained between cover 12 and device 16 for proper device performance. Thus, in this embodiment, spacer 26 should be 20 μm-50 μm thick. In addition, to facilitate the wafer scale fabrication process described below, an SU-8 spacer 26 can be comparatively narrow, as little as 50 μm for example, and still maintain adequate bonding. In the embodiment shown in FIG. 1, the width Wₓ of spacer 26 in the X direction (FIG. 1) is larger where there are no contact pads and the width W_{y} of spacer 26 is smaller in the Y direction (FIG. 1) near contact pads 30. The width of spacer 26 for any particular application may vary from that shown depending, for example, on the bond strength needed to meet process and reliability requirements for the application, the type of light sensitive adhesive used, and any limitations in the fabrication process. SU-8 photoresists and other such photo-definable adhesives are particularly advantageous for spectrophotometer packaging because the thickness and width of spacer 26 and its alignment to the underlying structure may be precisely defined. In addition, the techniques for processing these adhesive materials is comparatively clean, thus reducing the risk that debris or other contaminants will damage the delicate components in optical device 16 or alter the transparency characteristics of cover 12.

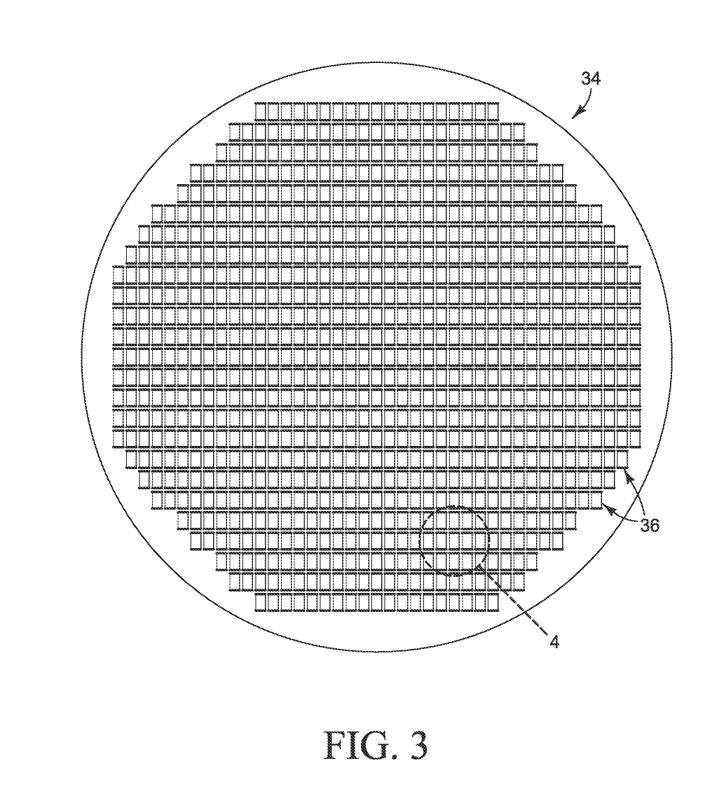

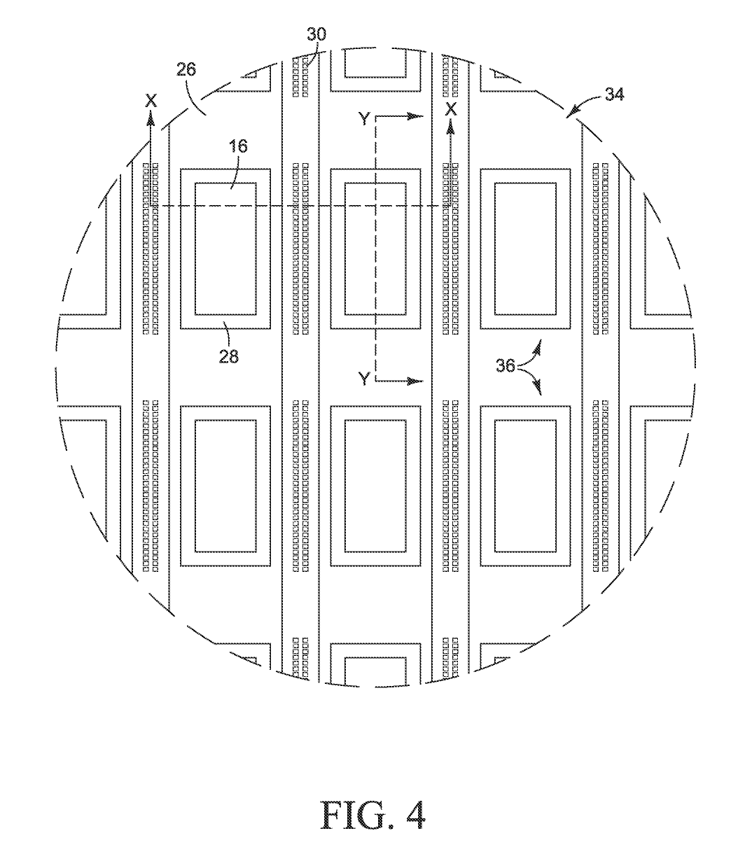

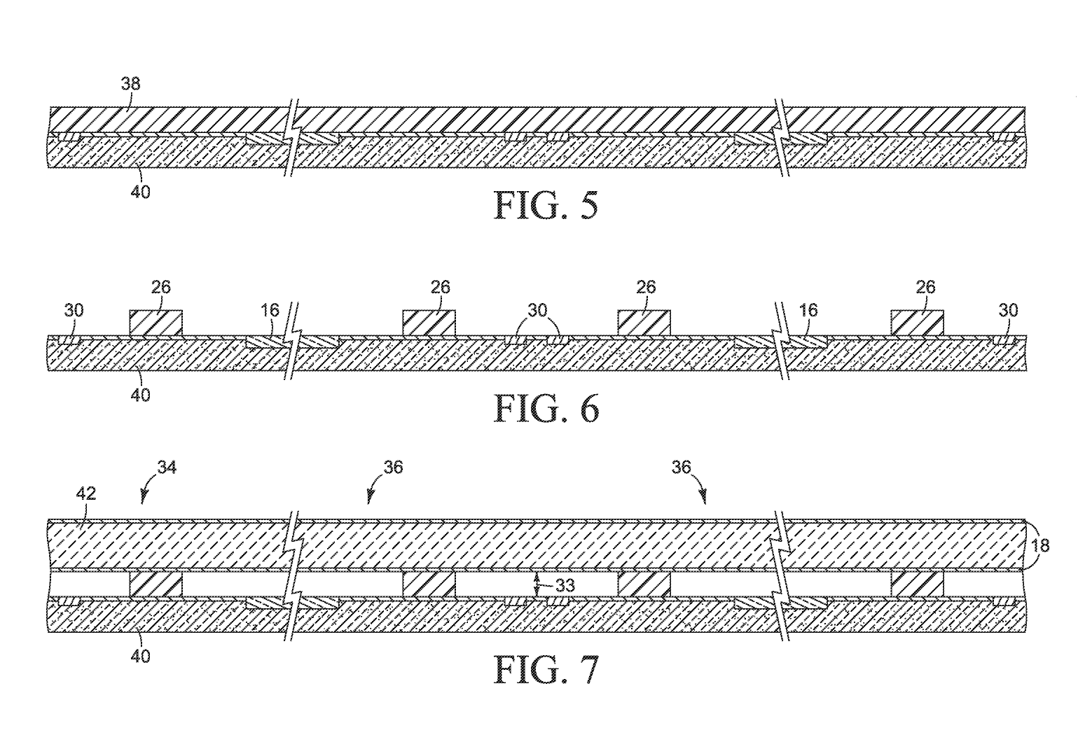

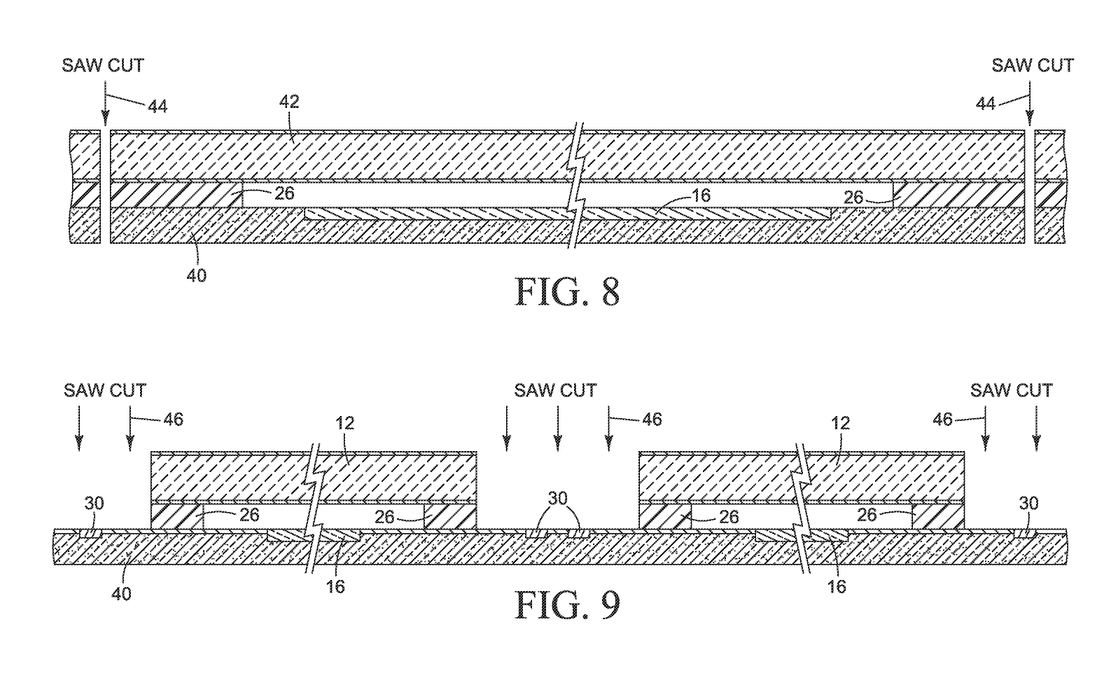

FIG. 3 is a plan view illustrating an in-process optical micro device wafer assembly 34 containing individual in-process device packages 36. FIG. 4 is a detail view of a portion of the wafer assembly 34 shown in FIG. 3. FIGS. 5-10 are section views illustrating one embodiment of a sequence of steps for fabricating wafer assembly 34 and singulating the individual device packages 36 from wafer assembly 34 to form packages 10 shown in FIGS. 1 and 2. FIGS. 5-7, 9 and 10 are taken along the X-X section line shown in FIG. 4. FIG. 8 is taken along the Y-Y section line shown in FIG. 4. Conventional techniques well known to those skilled in the art of semiconductor processing may be used to form the structures described below. Thus, the details of those techniques are not included in the description except where it may be desirable to a better understanding of the innovative aspects of an embodiment to describe a specific technique or processing parameter.

Referring first to FIG. 5, a layer of SU-8 or other suitable light sensitive adhesive material 38 is formed on a substrate wafer 40 to the desired thickness of spacers 26. Substrate wafer 40 represents a fully processed, or near fully processed, wafer that includes optical MEMS devices 16, contact pads 30 and any other operational components that may be integrated into the substrate. As shown in FIG. 6, layer 38 is selectively removed in the desired pattern of spacers 26 surrounding devices 16. (The pattern of spacer 26 is best seen in the plan views of FIGS. 1 and 4.) A glass or other suitable transparent cover wafer 42 is aligned with and bonded to substrate wafer 40 at spacers 26 as shown in FIG. 7 using, for example, a conventional wafer bonder. Cover wafer 42 represents a fully processed, or near fully processed, wafer that includes any anti-reflective and/or filter coatings 18. Although a coating 18 on the exposed outer surface 22 of cover wafer 42 may be formed after bonding, it is expected that any such coating 18 will usually be formed prior to alignment with and bonding to substrate wafer 40.

An SU-8 photoresist used for spacers 26, for example, will cure fully at a temperatures in the range of 100° C.-200° C., thus avoiding the higher temperatures needed to seal the glass covers used in a conventional ceramic optical MEMS device package. The lower bonding temperature protects anti-reflective coatings 18 on cover 12, which can delaminate at higher temperatures, and reduces the risk of damage to device 16 and other components in substrate wafer 40 from the material stresses induced by high temperature bonding. It is expected that SU-8 and other negative photoresists will be desirable for most optical MEMS packaging applications due to low curing temperatures, excellent adhesive qualities, and precise structural alignment/definition characteristics. However, other suitable light sensitive, photo definable adhesives fully curable at temperatures less than 300° C. may be used. For example, IJ5000™ (commercially available from E. I. DuPont Company) and other such polymeric adhesives used as a so-called “barrier” layer in inkjet printheads may also be suitable for spacers 26.

Referring now to the section view of FIG. 8 (which corresponds to the Y-Y section line in FIG. 4), individual device packages 36 are singulated from wafer assembly 34 by first sawing or otherwise cutting wafer assembly 34 between packages 36 in the X direction (FIG. 4), as indicated by saw cut arrows 44 in FIG. 8. Referring to FIG. 9, cover wafer 42 is cut through to gap 33 in the Y direction (FIG. 4) to expose contact pads 30, as indicated by saw cut arrows 46 in FIG. 9. Rotating the saw blade up, away from substrate wafer 40 helps minimize the risk of damage to bond pads 30 during cutting. With an upward rotating saw blade, it is expected that a gap 33 as small as 5 μm will provide sufficient clearance to the saw blade so that pre-trenching transparent cover wafer 42 at the cut locations is not required. In FIG. 10, a second cut is made in the Y direction between rows of contact pads 30, as indicated by saw cut arrows 48 in FIG. 10, to complete the singulation of individual packages 36, thus forming each individual package 10 described above with reference to FIGS. 1 and 2. Other singulation sequences may be used. For example, it may be desirable in some applications to expose contact pads 30 first, and then cut in the X and Y directions to singulate individual die packages 36 from wafer assembly 34.

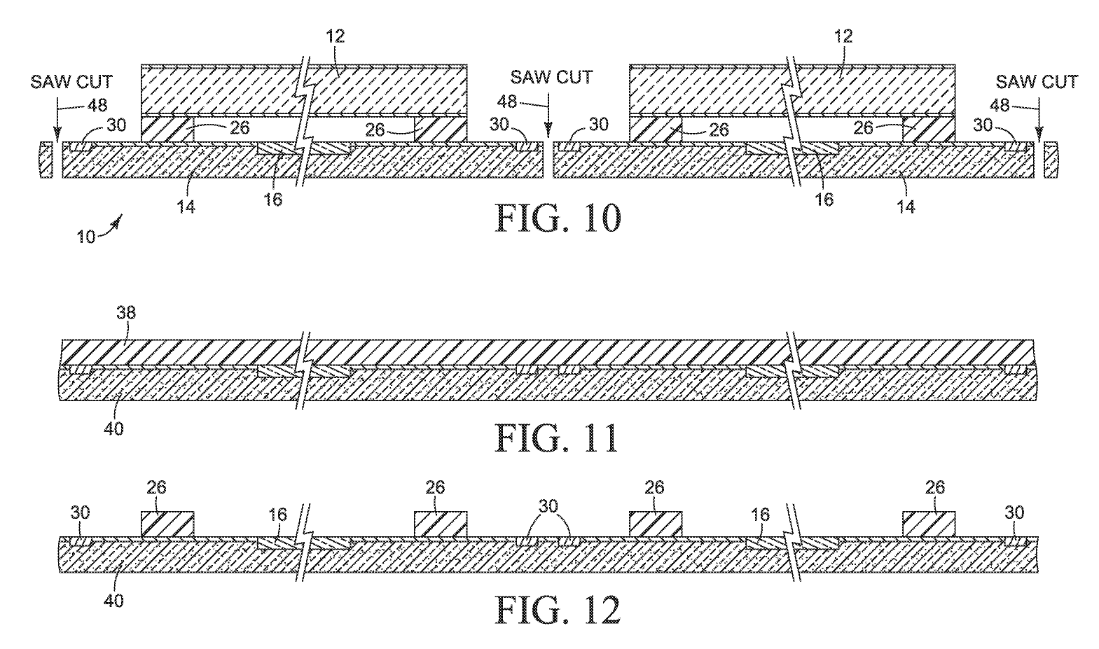

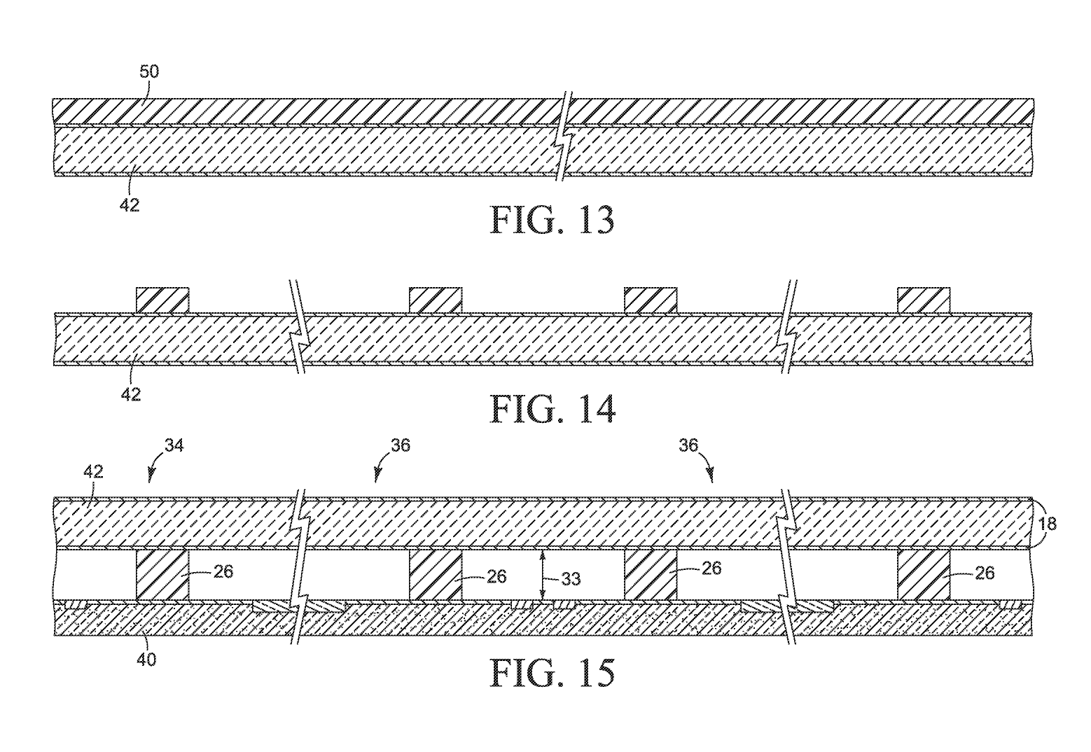

In an alternative embodiment shown in FIGS. 11-15, a layer of SU-8 or other suitable light sensitive adhesive material is formed on substrate wafer 40 (layer 38 in FIG. 11) and on cover wafer 42 (layer 50 in FIG. 13). The combined thickness of layers 38 and 50 corresponds to the desired thickness of spacers 26. Layers 38 and 50 are selectively removed in the pattern of spacers 26 surrounding devices 16, as shown in FIGS. 12 and 14, respectively. The two wafers 40 and 42 are then bonded together as shown in FIG. 15. Singulation may proceed as described above with reference to FIGS. 8-10. Each adhesive layer 38 and 50 need not be the same thickness or formed from the same adhesive material (although, of course, different adhesive materials must be compatible). For example, it may be desirable in some packaging sequences for some optical devices 16 to form only a thin film of a transparent adhesive material on cover wafer 42 and proceed with bonding under vacuum without first having to remove any of the transparent adhesive film.

“A” or “an” in the claims means one or more when introducing an element of the claim. For example, “a solid state light sensor” in claim 1 means on or more solid state light sensors. “And/or” in the claims means one or the other or both.

As noted at the beginning of this Description, the exemplary embodiments shown in the figures and described above illustrate but do not limit the invention. Other forms, details, and embodiments may be made and implemented. Therefore, the foregoing description should not be construed to limit the scope of the invention, which is defined in the following claims.

What is claimed is:

1. A method for making an optical micro device package, comprising:
providing a substrate wafer having a plurality of solid state light sensors integrate therein;
providing a transparent cover wafer coated with a material that alters the transparency characteristics of the cover wafer;
forming a layer of light sensitive, photo definable adhesive material on the substrate wafer and/or on the cover wafer;
selectively removing part of the layer of adhesive material, or selectively removing parts of one or both layers of adhesive material if more than one layer has been formed, in a pattern for a plurality of adhesive spacers between the substrate wafer and the cover wafer with each spacer surrounding a corresponding one of the light sensors;
bonding the substrate wafer and the cover wafer together at the spacers to form a wafer assembly in which each spacer surrounds and seals a corresponding one of the light sensors within a cavity bounded by a spacer and the two wafers; and
singulating individual device packages from the wafer assembly.

2. The method of claim 1, wherein singulating individual device packages from the wafer assembly comprises:
in a first cutting operation at first locations, cutting through the cover wafer into a gap between the wafers formed by the spacers to uncover contact pads on the substrate wafer; and then
in a second cutting operation at the first locations, cutting through the substrate wafer.

3. The method of claim 2, wherein the first cutting operation includes rotating a cutting blade up, away from the substrate wafer into the gap between the wafers to uncover the contact pads.

4. The method of claim 3, wherein the first cutting operation is performed without first pre-trenching or otherwise thinning the cover wafer at contact pad locations.

5. The method of claim 1, wherein selectively removing further comprises selectively removing in a pattern for a plurality of adhesive spacers that are each 20 μm-50 μm thick between the substrate wafer and the cover wafer.

6. The method of claim 1, wherein bonding the substrate wafer and the cover wafer together at the spacer comprises fully curing the adhesive material at a temperature less than 300°.

7. The method of claim 1, wherein forming a layer of light sensitive adhesive material on the substrate wafer and/or on the cover wafer comprises forming a layer of light sensitive material on only the substrate wafer.

8. The method of claim 1, wherein providing a transparent cover wafer coated with a material that alters the transparency characteristics of the cover wafer comprises providing a transparent cover wafer coated with an anti-reflective and/or a light filtering material.

9. A method for making optical micro device packages, comprising:
integrating a plurality of solid state light sensors and contact pads into a substrate wafer, the contact pads being arranged in pairs of parallel rows with each pair extending along the first substrate wafer between adjacent light sensors;
coating a transparent cover wafer with a material that alters the transparency characteristics of the cover wafer;
forming a layer of light sensitive, photo definable adhesive material on the substrate wafer and/or on the cover wafer;
selectively removing part of the layer of adhesive material, or selectively removing parts of one or both layers of adhesive material if more than one layer has been formed, in a pattern for:
a plurality of adhesive spacers between the substrate wafer and the cover wafer with each spacer surrounding a corresponding one of the light sensors; and
leaving the contact pads uncovered by adhesive material;
bonding the substrate wafer and the cover wafer together at the spacers to form a wafer assembly in which each spacer surrounds a corresponding one of the light sensors within a cavity bounded by a spacer and the two substrates and leaving the contact pads uncovered by adhesive material in a gap between the two substrates;
singulating individual device packages from the wafer assembly by:
in a first cutting operation, cutting completely through the wafer assembly between light sensors in a first direction;
in a second cutting operation, cutting through the cover wafer into the gap in a second direction perpendicular to the first direction to uncover contact pads on the substrate wafer; and then
in a third cutting operation, cutting through the substrate wafer in the second direction between adjacent rows of contact pads to complete singulating individual device packages from the wafer assembly.

10. The method of claim 9, wherein the second cutting operation is performed without first pre-trenching or otherwise thinning the cover wafer at contact pad locations.

11. The method of claim 9, wherein bonding the substrate wafer and the cover wafer together at the spacers comprises fully curing the adhesive material at a temperature less than 300°.

12. The method of claim 9, wherein coating a transparent cover wafer with a material that alters the transparency characteristics of the cover wafer comprises coating the cover wafer with an anti-reflective and/or a light filtering material.

13. A package for a micro-device, comprising:
a solid state light sensor integrated into a substrate;
a transparent cover covering the light sensor, the cover having a coating thereon that alters the transparency characteristics of the cover; and
a spacer surrounding the light sensor between the substrate and the cover, the spacer comprising a fully cured light sensitive, photo definable adhesive material and the spacer defining a gap of 20 μm-50 μm between the light sensor and the cover.

14. The package of claim 13, wherein the spacer comprises a fully cured negative photoresist.

15. The package of claim 13, wherein the coating on the cover comprises an anti-reflective coating.
